(19) United States
(12) Patent Application Publication
(10) Pub. No.: US 2025/0092519 A1
(43) Pub. Date: Mar. 20, 2025

(54) METHODS AND SYSTEM FOR MITIGATING CVD FORELINE GROWTH

(71) Applicant: ASM IP Holding B.V., Almere (NL)

(72) Inventors: Jereld Lee Winkler, Gilbert, AZ (US); Petri Raisanen, Gilbert, AZ (US)

(21) Appl. No.: 18/830,706

(22) Filed: Sep. 11, 2024

Related U.S. Application Data
(60) Provisional application No. 63/538,762, filed on Sep. 15, 2023.

(51) Int. Cl. C23C 16/455

(52) U.S. Cl. CPC C23C 16/45561; C23C 16/45544

(57) ABSTRACT

Various embodiments of the present technology may provide a system with a bypass line to a foreline of a reaction chamber. The system may include a pump coupled to the foreline. The system may include a pressure-flow controller upstream from the bypass line. The bypass line may be coupled to the foreline at the pump inlet. The bypass line may include a low-flow pathway where the conductance is between 1% and 10% relative to unrestricted flow. The bypass line can comprise a decomposition device configured to decompose the fluid (e.g., gas) in the bypass line.

### CROSS-REFERENCE TO RELATED APPLICATIONS

This application is a nonprovisional of, and claims priority to and the benefit of, U.S. Provisional Patent Application No. 63/538,762, filed Sep. 15, 2023 and entitled “METHODS AND SYSTEM FOR MITIGATING CVD FORELINE GROWTH,” which is hereby incorporated by reference herein.

### FIELD OF INVENTION

The present disclosure generally relates to a method and system for mitigating CVD foreline growth. More particularly, the present disclosure relates to utilizing a pressure controller to meter dose, relocating the bypass termination to be adjacent to the pump inlet, and/or decomposing the gas before reaching, or within, the foreline.

### BACKGROUND OF THE TECHNOLOGY

Semiconductor processing equipment that perform deposition may suffer from CVD growth in unwanted areas of the processing equipment. In particular, in an ALD process, where a precursor is pulsed with a co-reactant, excess CVD growth may be observed in the foreline due to the co-reactant coexisting with the precursor. This CVD growth can form low-density powder that is poorly adhered to the inner walls of the foreline and can periodically break away from the walls and be transported to the pump, causing pump failures.

### SUMMARY OF THE INVENTION

Various embodiments of the present technology may provide a system with a bypass line to a foreline of a reaction chamber. The system may include a pump at coupled to the foreline. The system may include a pressure-flow controller upstream from the bypass line. The bypass line may be coupled to the foreline at the pump inlet. The bypass line may include a low-flow pathway where the conductance is between 1% and 10%.

According to one aspect, a system comprises: a reaction chamber; a first vessel configured to contain a precursor, wherein the first vessel is coupled to the reaction chamber with a first gas line; a second vessel configured to contain a co-reactant, wherein the second vessel is coupled to the reaction chamber; a foreline comprising a first end coupled directly to the reaction chamber and an opposing second end; a pump coupled to the second end of the foreline at a first junction; a second gas line comprising a first section coupled to an inlet of the reaction chamber and a second section coupled to the foreline; wherein the first section and the second section are connected to each other at a second junction; a mass flow controller coupled between the second vessel and the second junction.

In one embodiment, the co-reactant is one of ozone, ammonia, silane, or disilane.

In one embodiment, the first section of the second gas line has a first conductance and the second section has a second conductance, wherein the first conductance is the same as the second conductance.

In one embodiment, the co-reactant has a high-pressure gas state.

In one embodiment, the system further comprises a first valve within the first section of the second gas line and a second valve within the second section of the second gas line.

In one embodiment, the system further comprises a control unit configured to transmit control signals to the first and second valves.

In one embodiment, the pump is a dry vacuum pump.

In one embodiment, the system further comprises a decomposition device coupled to the second section of the second gas line and configured to decompose the co-reactant. The decomposition device can comprise a catalyst and/or a heater.

In another aspect, a system comprises: a reaction chamber; a foreline comprising a first end coupled directly to the reaction chamber and an opposing second end; a pump coupled to the second end of the foreline; a first vessel configured to contain a precursor, wherein the first vessel is coupled to the reaction chamber with a first gas line; a second vessel configured to contain a co-reactant, wherein the second vessel is coupled to the reaction chamber; a second gas line comprising a first section coupled to an inlet of the reaction chamber, a second section coupled to the foreline and a third section coupled to the foreline; wherein the first section and the second section are connected to each other at a junction; and wherein the second and third sections are in parallel with each other; and a pressure-flow controller coupled between the second vessel and the second junction.

In one embodiment, the system further comprises a first valve within the first section of the second gas line, a second valve within the second section of the second gas line, and a third valve within the third section of the second gas line.

In one embodiment, the system further comprises a flow restrictor coupled between the junction and the third valve.

In one embodiment, the system further comprises a control unit configured to transmit control signals to the first, second, and third valves.

In one embodiment, the co-reactant is one of ozone, ammonia, silane, or disilane.

In one embodiment, the first section has a first conductance, the second section has a second conductance, and the third section has a third conductance, wherein the third conductance is 95% less than the first conductance and/or the second conductance.

In one embodiment, the pump can be a dry vacuum pump.

In yet another aspect, a system comprises: a reaction chamber; a foreline comprising a first end coupled directly to the reaction chamber and an opposing second end; a pump coupled to the second end of the foreline at a first junction; a first vessel configured to contain a precursor, wherein the first vessel is coupled to the reaction chamber with a first gas line; a second vessel configured to contain a co-reactant, wherein the second vessel is coupled to the reaction chamber; a second gas line comprising a first section coupled to an inlet of the reaction chamber and a second section coupled to the first junction; wherein the first section and the second section are connected to each other at a second junction.

In one embodiment, the system further comprises a pressure-flow controller coupled between the second vessel and the second junction. The second gas line further comprises a third section coupled between the second junction and the foreline. The second section and the third section can be in parallel with each other.

In one embodiment, the pump can be a dry vacuum pump.

In one embodiment, the first section has a first conductance, the second section has a second conductance, and the third section has a third conductance, wherein the third conductance is 95% less than the first conductance and/or the second conductance.

In one embodiment, the system further comprises a first valve within the first section of the second gas line, a second valve within the second section of the second gas line, and a third valve within the third section of the second gas line.

In one embodiment, the system further comprises a flow restrictor coupled to the third section between the second junction and the third valve.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with an embodiment of the present technology.

FIG. 2 representatively illustrates a system in accordance with an alternative embodiment of the present technology.

FIG. 3 representatively illustrates a system in accordance with an alternative embodiment of the present technology.

FIG. 4 representatively illustrates a system in accordance with an alternative embodiment of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various reaction chambers, valves and valve manifolds, gas line connectors, and vessels. The components in any of the depicted embodiments in the figures can be combined and/or arranged in any suitable combination of components within a system (i.e., a component depicted in one embodiment in a first figure but not in a second figure can also be implemented in the second figure, in accordance with the disclosure).

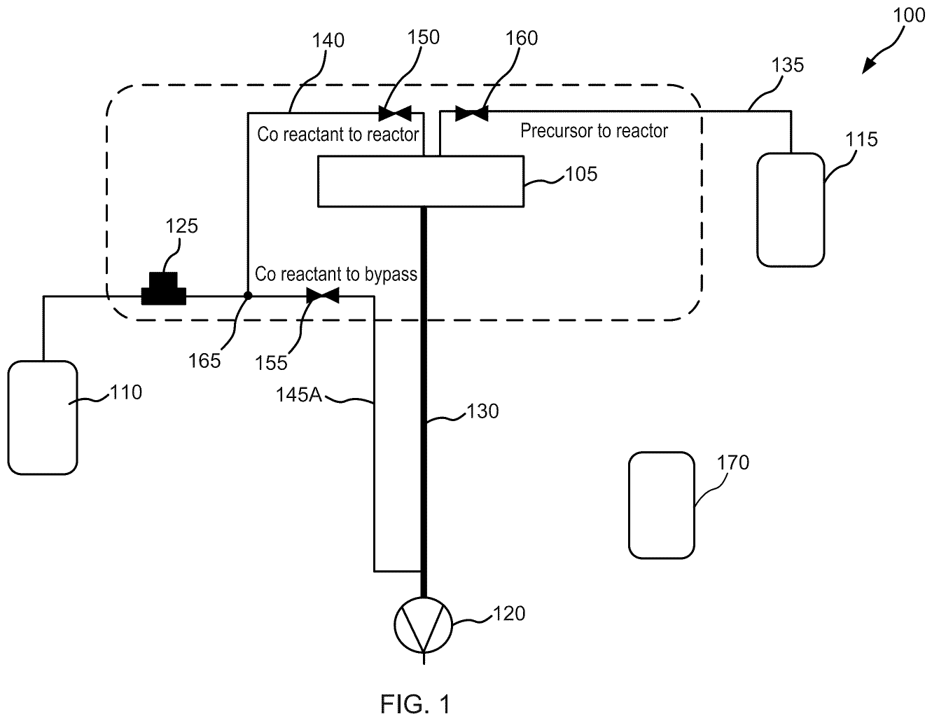

Referring to FIGS. 1-4, an exemplary system 100 may comprise a reaction chamber 105, a first vessel 115, a second vessel 110, a foreline 130, and a pump 120.

In various embodiments, the reaction chamber 105 may be configured to deposit a film on a substrate, such as a wafer. The reaction chamber 105 may be configured for any desired deposition process.

In various embodiments, the first vessel 115 may be configured to contain or otherwise hold a first chemical (e.g., a precursor). The first chemical may be in the form of a solid, a liquid, or a gas. In some cases, the first vessel 115 may be configured to sublimate the first chemical into a gas. For example, the first vessel 115 may comprise heating elements and/or a sublimator.

In various embodiments, the second vessel 110 may be configured to contain or otherwise hold a second chemical (e.g., a co-reactant). The second chemical may comprise a chemical with a high-pressure gas state, such as ozone, ammonia, silane, or disilane. The second vessel 110 may be configured to sublimate the second chemical into a gas. For example, the second vessel 110 may comprise heating elements and/or a sublimator.

In various embodiments, the foreline 130 may be coupled to the reaction chamber 105, and may be configured to exhaust excess chemicals from the reaction chamber 105. For example, the foreline may comprise a first end coupled to an opening in a bottom surface of the reaction chamber 105 and an opposing, second end. The foreline 130 may be formed from any suitable material, such as a metal material, for example a stainless steel.

In various embodiments, the pump 120 may be configured to facilitate evacuation of the reaction chamber 105. For example, an inlet of the pump 120 may be coupled to the second end of the foreline 130. The connection point of the inlet of the pump 120 and the foreline 130 may be referred to as a first junction. The pump 120 may comprise a vacuum pump. An outlet of the pump 120 may output the gas into a waste line (not shown).

In various embodiments, the system 100 may further comprise a first gas line 135 configured to couple the first vessel 115 to an inlet of the reaction chamber 105. The first gas line 135 may formed from any suitable material, such as stainless steel. The first gas line may comprise any number of couplings, connectors, gas line portions, and the like.

In various embodiments, the system 100 may further comprise a second gas line. The second gas line may be formed from any suitable material, such as stainless steel. In an exemplary embodiment, the second gas line comprises a first section 140 (i.e., a main delivery line) configured to deliver a gas to the reaction chamber 105. For example, a first end of the first section 140 may couple to or otherwise connect to the second vessel 110 and a second end of the first section 140 may couple to or otherwise connect to the inlet of the reaction chamber 105.

In an exemplary embodiment, the second gas line may further comprise a second section (e.g., a first bypass line), e.g., second section 145A or 145B. The second section may comprise a first end and an opposing, second end. The first end of the second section 145A may connect to the first section 140 at a second junction point 165 (or at any other suitable location), and the second end of the second section 145A may connect to the first junction. The first end of the second section 145B may connect to the first section 140 at second junction point 165 (or at any other suitable location), and the second end of the second section 145B may connect to the foreline 130.

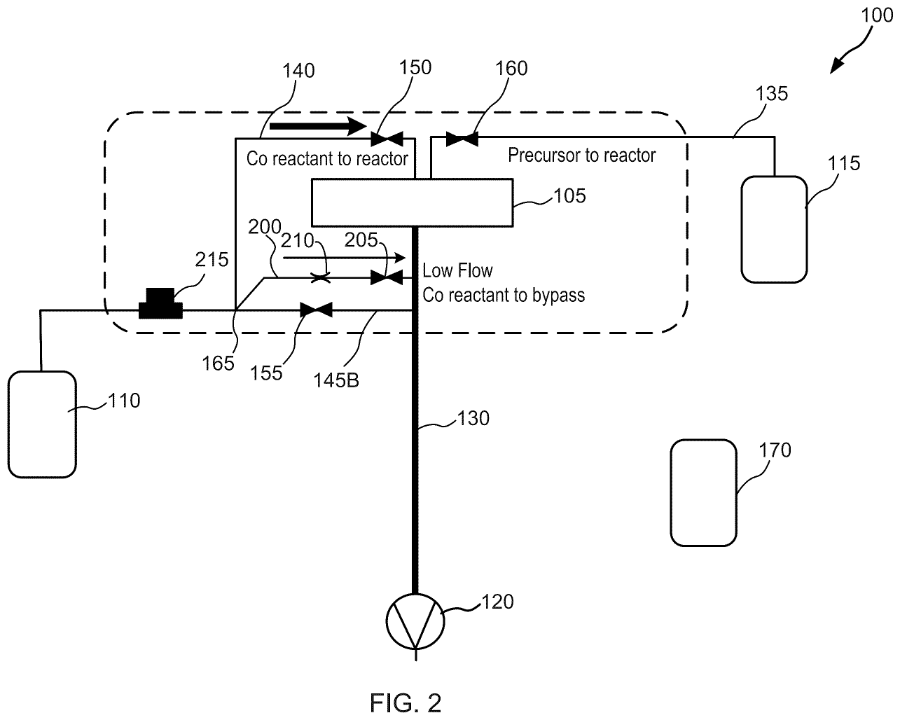

In an exemplary embodiment, and referring to FIG. 2, the second gas line may further comprise a third section 200 (e.g., a second bypass line). The third section 200 may comprise a first end coupled to the section junction 165 (or any other suitable location) and a second end coupled to the foreline 130.

In various embodiments, the system 100 may comprise various valves to restrict or allow the flow of gas through the gas lines. For example, the system 100 may comprise a first valve 160 within the first gas line 135, a second valve 150 within the first section 140, and a third valve 155 within the second section (e.g., second section 145A or 145B).

The first valve 160 may be disposed between the inlet of the reaction chamber 105 and an outlet of the first vessel 115. The first valve 160 may comprise any suitable valve type. In an exemplary embodiment, the first valve 160 may comprise a diaphragm valve that is responsive to a control signal. The control signal may open or close the valve.

The second valve 150 may be disposed between the second junction 165 and the inlet of the reaction chamber 105. The second valve 150 may comprise any suitable valve type. In an exemplary embodiment, the second valve 150 may comprise a diaphragm valve that is responsive to a control signal. The control signal may open or close the valve.

The third valve 155 may be disposed between the first junction and section junction 165, or between the second junction and the foreline 130. The second valve 150 may comprise any suitable valve type. In an exemplary embodiment, the third valve 155 may comprise a diaphragm valve that is responsive to a control signal. The control signal may open or close the valve.

In addition, in an exemplary embodiment, the third section 200 may comprise a fourth valve 205 and/or a restrictor 210. The fourth valve 205 and the restrictor 210 may be disposed between the second junction 165 and the foreline 130. The restrictor 210 may be arranged upstream from the fourth valve 205. The fourth valve 205 may comprise any suitable valve type. In an exemplary embodiment, the fourth valve 205 may comprise a diaphragm valve that is responsive to a control signal. The control signal may open or close the valve.

In various embodiments comprising the third section 200, there may be no second section 145B. In various embodiments, there may be no third section 200, but a flow restrictor can be coupled to the second section 145B.

In one embodiment, and referring to FIGS. 1, 3, and 4, the system 100 may further comprise a mass flow controller 125. The mass flow controller 125 may be coupled to the second gas line between an outlet of the second vessel 110 and the second junction point 165. In particular, the mass flow controller 125 may be arranged upstream from the second junction point 165. In various embodiments, there may be a pressure-flow controller (e.g., similar to pressure-flow controller 215) in addition to, or in place, of mass flow controller 125.

In another embodiment, and referring to FIG. 2, the system 100 may further comprise a pressure-flow controller (PFC) 215 configured to regulate the flow rate and conductance of the second gas line. The PFC 215 may be coupled to the second gas line between an outlet of the second vessel 110 and the second junction point 165. In particular, the PFC 215 may be arranged upstream from the second junction point 165. The PFC 215 may be configurable, for example, to be set to a desired pressure set point (e.g., a relatively higher set point pressure can cause greater flow, and a relatively lower set point pressure can cause less flow). The PFC 215 may be any suitable type of PFC that regulates gas flow according to pressure. In various embodiments, there may be a mass flow controller (e.g., similar to mass flow controller 125) in addition to, or in place of PFC 215.

In various embodiments, the system 100 may further comprise a control unit 170. Control unit 170 can be in electronic communication with any other suitable component(s) of system 100 (e.g., to generate and transmit valve control signals and/or control the mass flow controller and/or PFC). The control unit may also be used to set the set point of the PFC 215.

In operation, the system 100 may perform an atomic layer deposition (ALD) process. For example, the system 100 may perform a sequence of pulsing with the precursor and the co-reactant and purging steps in between pulsing with an inert gas, such as argon.

In conventional systems, a full flow of co-reactant into the foreline (e.g., during purge of the second gas line, and/or during pulsing or purging of the precursor) may result in a CVD reaction with the precursor happening within the foreline (e.g., on the sidewalls of the foreline). This is undesirable because this buildup can break away from the sidewalls and enter the pump, which may cause the pump to fail.

Embodiments of the present technology may mitigate CVD foreline buildup. For example, in operation and referring to FIG. 1, during pulsing of the co-reactant, the second valve 150 is open and the third valve 155 is closed. During purging of the co-reactant and/or pulsing and purging of the precursor, the second valve 150 is closed, and the third valve 155 is open. During purging, the gas is flowed through the second section 145A and directly to the inlet of the pump 120 (e.g., to the first junction), therefore bypassing most or all of the foreline 130, and thus mitigating or preventing CVD buildup along most the entire length of the foreline 130. Second section 145A can couple to the foreline 130 at or near the inlet of the pump 120, and/or second section 145A can couple to the pump 120 at a separate inlet than the pump inlet coupling to the foreline 130.

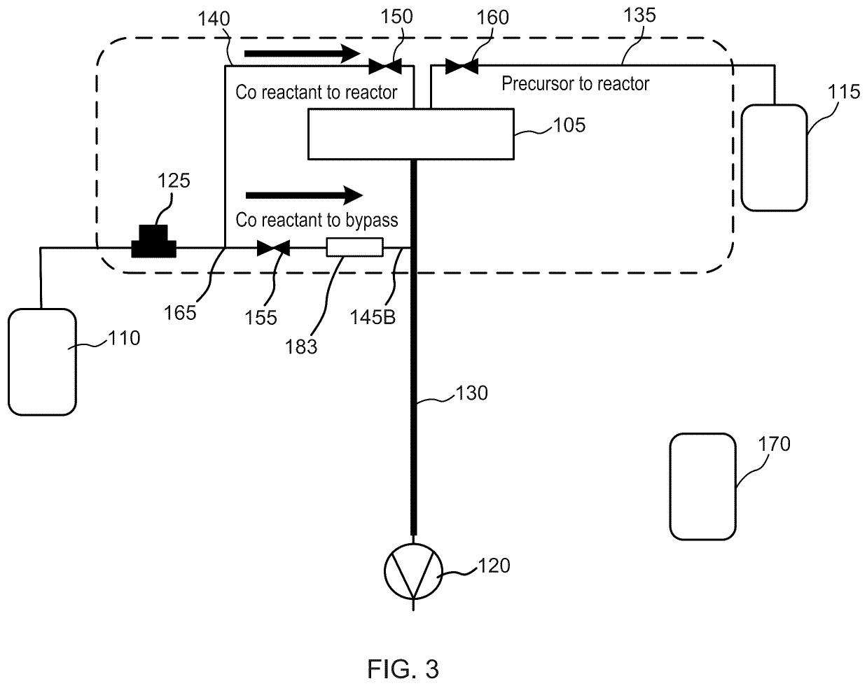

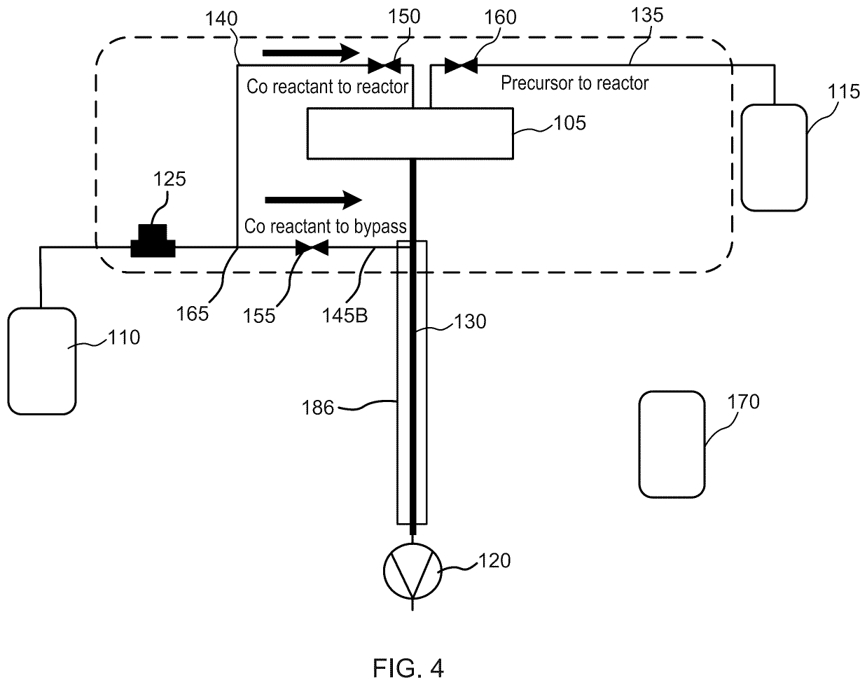

As another example, referring to FIGS. 3 and 4, at least a portion of the second section of the second gas line and/or the foreline 130 can comprise a decomposition device configured to decompose the co-reactant. For example, the second section 145B of the second gas line can comprise decomposition device 183 disposed along at least a portion of the second section 145B (e.g., between the second junction point 165 and the foreline 130). The decomposition device can be configured to decompose the co-reactant before reaching the foreline 130. As another example, the foreline 130 can comprise decomposition device 186 disposed along at least a portion of the foreline 130 (e.g., to decompose the co-reactant and/or any other gases therein, such as a precursor). The decomposition device can also be disposed along at least a portion of the second section of the second gas line and the foreline 130. Thus, by decomposing the co-reactant in the decomposition device, reaction between the co-reactant and the precursor is reduced or prevented, mitigating or preventing film formation and/or buildup within the foreline 130.

In various embodiments, the decomposition device can be any suitable structure or device to decompose gas flowing through the respective gas line (e.g., the co-reactant and/or the precursor). For example, the decomposition device can comprise a heater device (e.g., a heater coupled to and/or disposed about the second section of the second gas line and/or the foreline 130). The heater device can be configured to heat the gas (e.g., co-reactant) within the respective gas pathway (e.g., the second section of the second gas line and/or the foreline 130) to decompose the gas flowing therethrough via thermal decomposition. The heater device can be configured to heat the gas to temperatures that can cause the gas (e.g., the co-reactant) to at least partially, or substantially or completely, decompose. For example, to decompose a gas, a heating temperature can be selected to cause the half-life of the respective gas to be less than ten seconds, less than five seconds, less than two seconds, less than one second, and/or less than 0.5 second. For a gas comprising ozone, for example, the temperature to which the gas is heated can be about or at least 200° C., above 200° C., 200-400° C., 200-300° C., and/or the like. For a gas comprising silane and/or disilane, for example, the temperature to which the gas is heated can be about or at least 200° C. or 300° C., 200-400° C., 200-300° C., 300-400° C., and/or the like. For a gas comprising ammonia, for example, the temperature to which the gas is heated can be about or at least 400° C., 400-700° C., 400-600° C., 400-500° C., and/or the like. (“About” in this context means plus or minus 50° C.).

As another example, the decomposition device can comprise a catalyst device (e.g., catalytic bed) configured to receive and decompose the gas within the respective gas pathway (e.g., the second section of the second gas line and/or the foreline 130) via catalytic decomposition. The catalyst device can comprise a body housing a catalyst. The catalyst can be any suitable material or compound configured to at least partially decompose the gas, and can be selected based on the co-reactant or other gas to be decomposed. For example, to decompose a gas, the catalyst can be selected to cause the half-life of the respective gas to be less than ten seconds, less than five seconds, less than two seconds, less than one second, and/or less than 0.5 second.

For example, for a co-reactant comprising ozone, the catalyst can comprise a metal and/or metal oxide. The metal can be any suitable metal (e.g., a transition metal), such as platinum, palladium, ruthenium, copper, tungsten, copper, silver, tin, nickel, iron, gold, iridium, rhodium, cerium, manganese, cobalt, titanium, zinc, vanadium, chromium, molybdenum, and/or any combinations thereof. The metal oxide can comprise an oxide of any of the foregoing (e.g., manganese oxide). The catalyst can comprise other oxide materials (e.g., ceramic materials) such as silicon oxide, aluminum oxide, zirconium oxide, and/or the like. The catalyst can comprise a metal or metal oxide supported by another material (e.g., a ceramic material), such as manganese oxide supported by silicon oxide, aluminum oxide, zirconium oxide, and/or titanium oxide. The catalyst can comprise carbon or a carbon material (e.g., activated carbon, carbon black, graphite, carbon fiber, and/or the like). The catalyst for a co-reactant comprising ozone can decompose ozone (e.g., to oxygen (O₂)), which may not react with precursor in the foreline 130, thus mitigating or preventing build-up in the foreline 130.

In various embodiments, the decomposition device can comprise multiple components to decompose the respective gas (e.g., a catalyst and a heater).

As another example, referring to FIG. 2, the PFC 215 may be set to a desired pressure set point to achieve a desired flow of co-reactant to the reaction chamber 105. In an exemplary embodiment, the third section 200 may be set to have a conductance of between 1% and 10%, or about 5%, relative to the conductance through the first section 140 (e.g., the reduced conductance of the third section 200 can be relative to unrestricted flow through a flow path) (in this context, “about” means plus or minus 3%). The conductance through the third section 200 can be set (e.g., restricted) by the restrictor 210 and/or the fourth valve 205. Accordingly, the third section may have a conductance that is 95% less than the conductance of the first section and/or the second section of the second gas line. In this case, in response to second valve 150 and/or third valve 155 being closed, and fourth valve 205 being open (e.g., during a time when the co-reactant is not being provided to the reaction chamber 105), this relatively restricted and/or low co-reactant flow rate through the third section 200 reduces the amount of co-reactant to the foreline 130. Thus reaction between the co-reactant and the precursor is reduced or prevented, mitigating or preventing film formation and/or buildup within the foreline 130.

In various embodiments, the third section 200 can comprise a decomposition device disposed along at least a portion of the third section 200 (similar to the decomposition device(s) described in relation to FIGS. 3 and 4).

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises,” “comprising,” or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. A system, comprising:
a reaction chamber;
a first vessel configured to contain a precursor, wherein the first vessel is coupled to the reaction chamber with a first gas line;
a second vessel configured to contain a co-reactant, wherein the second vessel is coupled to the reaction chamber;
a foreline comprising a first end coupled directly to the reaction chamber and an opposing second end;
a pump coupled to the second end of the foreline at a first junction;
a second gas line comprising a first section coupled to an inlet of the reaction chamber and a second section coupled to the foreline; wherein the first section and the second section are connected to each other at a second junction; and
a mass flow controller coupled between the second vessel and the second junction.

2. The system according to claim 1, wherein the co-reactant is one of ozone, ammonia, silane, or disilane.

3. The system according to claim 1, wherein the first section of the second gas line has a first conductance and the second section has a second conductance, wherein the first conductance is the same as the second conductance.

4. The system according to claim 1, further comprising a first valve within the first section of the second gas line and a second valve within the second section of the second gas line.

5. The system according to claim 4, further comprising a control unit configured to transmit control signals to the first and second valves.

6. The system according to claim 1, further comprising a decomposition device coupled to the second section of the second gas line and configured to decompose the co-reactant.

7. The system according to claim 6, wherein the decomposition device comprises at least one of a catalyst or a heater.

8. A system, comprising:
a reaction chamber;
a foreline comprising a first end coupled directly to the reaction chamber and an opposing second end;
a pump coupled to the second end of the foreline;
a first vessel configured to contain a precursor, wherein the first vessel is coupled to the reaction chamber with a first gas line;
a second vessel configured to contain a co-reactant, wherein the second vessel is coupled to the reaction chamber;
a second gas line comprising a first section coupled to an inlet of the reaction chamber, a second section coupled to the foreline, and a third section coupled to the foreline; wherein the first section and the second section are connected to each other at a junction; and wherein the second and third sections are in parallel with each other; and
a pressure-flow controller coupled between the second vessel and the second junction.

9. The system according to claim 8, further comprising a first valve within the first section of the second gas line, a second valve within the second section of the second gas line, and a third valve within the third section of the second gas line.

10. The system according to claim 9, further comprising a flow restrictor coupled to the third section between the junction and the third valve.

11. The system according to claim 9, further comprising a control unit configured to transmit control signals to the first, second, and third valves.

12. The system according to claim 8, wherein the co-reactant is one of ozone, ammonia, silane, or disilane.

13. The system according to claim 8, wherein the first section has a first conductance, the second section has a second conductance, and the third section has a third conductance, wherein the third conductance is 95% less than the first conductance.

14. The system according to claim 8, wherein the pump is a dry vacuum pump.

15. A system, comprising:
a reaction chamber;
a foreline comprising a first end coupled directly to the reaction chamber and an opposing second end;
a pump coupled to the second end of the foreline at a first junction;
a first vessel configured to contain a precursor, wherein the first vessel is coupled to the reaction chamber with a first gas line;
a second vessel configured to contain a co-reactant, wherein the second vessel is coupled to the reaction chamber; and
a second gas line comprising a first section coupled to an inlet of the reaction chamber and a second section coupled to the first junction; wherein the first section and the second section are connected to each other at a second junction.

16. The system according to claim 15, further comprising a pressure-flow controller coupled between the second vessel and the second junction,
wherein the second gas line further comprises a third section coupled between the second junction and the foreline, and wherein the second and third sections are in parallel with each other.

17. The system according to claim 15, wherein the pump is a dry vacuum pump.

18. The system according to claim 16, wherein the first section has a first conductance, the second section has a second conductance, and the third section has a third conductance, wherein the third conductance is 95% less than the first conductance.

19. The system according to claim 16, further comprising a first valve within the first section of the second gas line, a second valve within the second section of the second gas line, and a third valve within the third section of the second gas line.

20. The system according to claim 19, further comprising a flow restrictor coupled to the third section between the second junction and the third valve.
